(19) United States
(12) Patent Application Publication
(10) Pub. No.: US 2021/0217783 A1
(43) Pub. Date: Jul. 15, 2021

(54) TRANSISTOR ARRAYS

(71) Applicant: Flexenable Limited, Cambridge (GB)

(72) Inventors: Josephine Socratous, Cambridge (GB); Herve Vandekerchove, Cambridge (GB)

(21) Appl. No.: 15/734,108

(22) PCT Filed: May 31, 2019
(86) PCT No.: PCT/EP2019/064223

§ 371 Date: Dec. 1, 2020

(30) Foreign Application Priority Data
Jun. 1, 2018 (GB) 1809028.2

(51) Int. Cl. H01L 27/12

(52) U.S. Cl. CPC H01L 27/1288; H01L 27/127; H01L 27/124

(57) ABSTRACT

A technique of producing a device comprising a stack of layers defining an array of transistors and including one or more electrically conductive connections between levels, wherein the method comprises: forming a source-drain conductor pattern defining an array of source conductors each providing an addressing line for a respective set of transistors of the transistor array, and an array of drain conductors each associated with a respective transistor of the transistor array; wherein forming said source-drain conductor pattern comprises: forming a first conductor subpattern which comprises conductor material at least in the regions of the addressing lines and provides the conductive surface of the source-drain conductor pattern at least in the regions where the source and drain conductors are in closest proximity; masking the first conductor subpattern in regions where the source and drain conductors are in closest proximity; thereafter forming a second conductor subpattern, which also comprises conductor material at least in the regions of the addressing lines and which provides the conductive surface of the source-drain conductor pattern in one or more interconnect regions where electrically conductive interlayer connections are to be formed to the source-drain conductor pattern; thereafter de-masking the first conductor subpattern in the regions where the source and drain conductors are in closest proximity; and patterning a layer of semiconductor channel material in situ over the source-drain conductor pattern.

Transistor arrays may be defined by a stack of layers comprising conductor, semiconductor and insulator layers.

One important part of the stack is the source-drain conductor pattern that defines the source and drain conductors of the transistor array, and the inventors for the present application have carried out research into: (i) improving the transfer of charge carriers between the semiconductor channel and source/drain conductors and (ii) improving conductive connections between the source-drain conductor pattern and conductors at one or more other levels in the stack.

There is hereby provided a method of producing a device comprising a stack of layers defining an array of transistors and including one or more electrically conductive connections between levels, wherein the method comprises: forming a source-drain conductor pattern defining an array of source conductors each providing an addressing line for a respective set of transistors of the transistor array, and an array of drain conductors each associated with a respective transistor of the transistor array; wherein forming said source-drain conductor pattern comprises: forming a first conductor subpattern which comprises conductor material at least in the regions of the addressing lines and provides the conductive surface of the source-drain conductor pattern at least in the regions where the source and drain conductors are in closest proximity; masking the first conductor subpattern in regions where the source and drain conductors are in closest proximity; thereafter forming a second conductor subpattern, which also comprises conductor material at least in the regions of the addressing lines and which provides the conductive surface of the source-drain conductor pattern in one or more interconnect regions where electrically conductive interlayer connections are to be formed to the source-drain conductor pattern; thereafter de-masking the first conductor subpattern in the regions where the source and drain conductors are in closest proximity; and patterning a layer of semiconductor channel material in situ over the source-drain conductor pattern.

According to one embodiment, the method further comprises: forming one or more layers over the source-drain conductor pattern in said one or more interconnect regions, and patterning said one or more layers to expose said source-drain conductor pattern in said one or more interconnect regions; and wherein the material of the first conductor sub-pattern exhibits a higher reduction in electrical conductivity than the material of the second conductor subpattern upon exposure to the conditions under which said patterning of said one or more layers is carried out.

According to one embodiment, the material of the second conductor subpattern exhibits substantially no reduction in electrical conductivity upon exposure to the conditions under which said patterning of said one or more layers is carried out.

According to one embodiment, said conditions comprise a plasma generated from a gas comprising oxygen.

According to one embodiment, said second conductor subpattern comprises conductor material at least in all regions where the first conductor pattern comprises conductor material outside the regions where semiconductor channel material is retained.

According to one embodiment, masking the first conductor subpattern comprises patterning a resist layer in situ on the first conductor subpattern to form an array of resist islands in an array of regions, and wherein patterning the layer of semiconductor channel material comprises forming an array of semiconductor channel materials, each semiconductor channel island substantially centred on a respective region of said array of regions, and comprising a magnified version of the shape of the respective resist island.

According to one embodiment, masking the first conductor subpattern comprises patterning a resist layer in situ on the first conductor subpattern, and wherein the method further comprises using the same photomask for both patterning said resist layer and patterning the layer of semiconductor channel material.

Embodiments of the present invention are described in detail below, by way of example only, with reference to the accompanying drawings, in which:

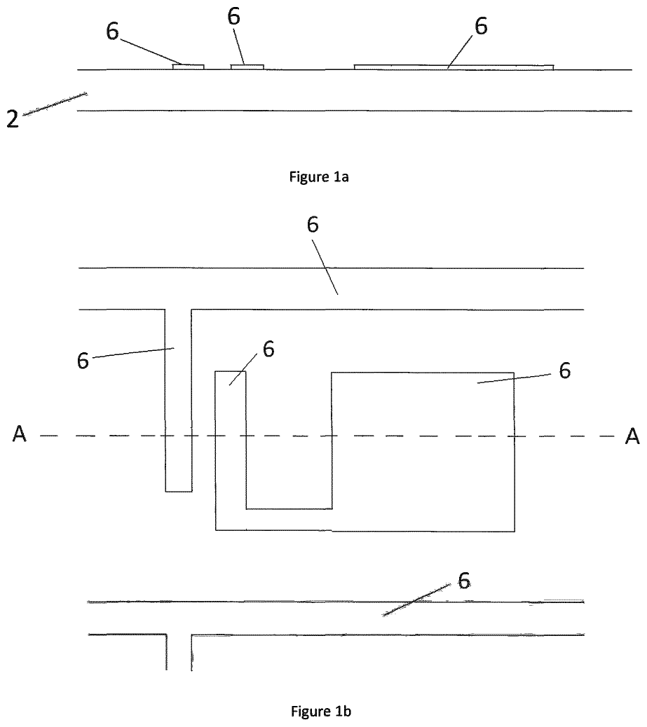

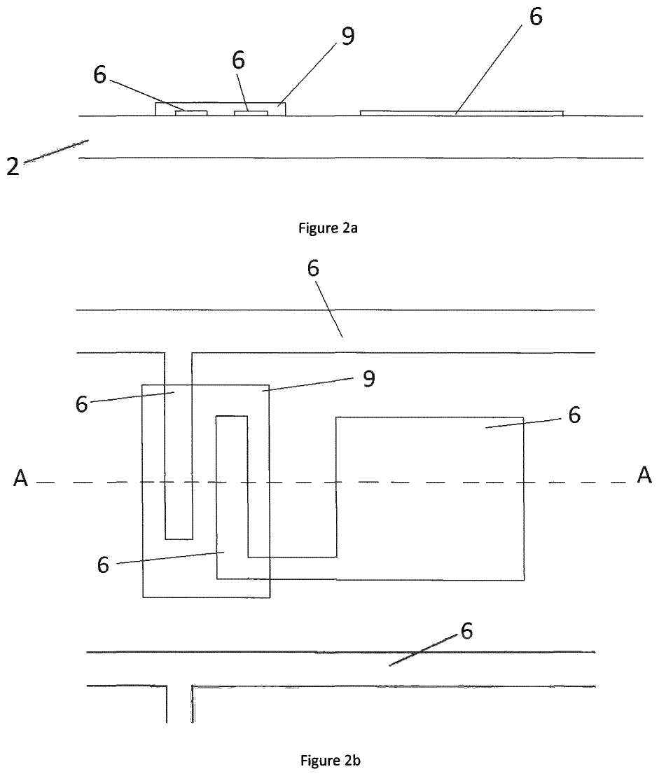

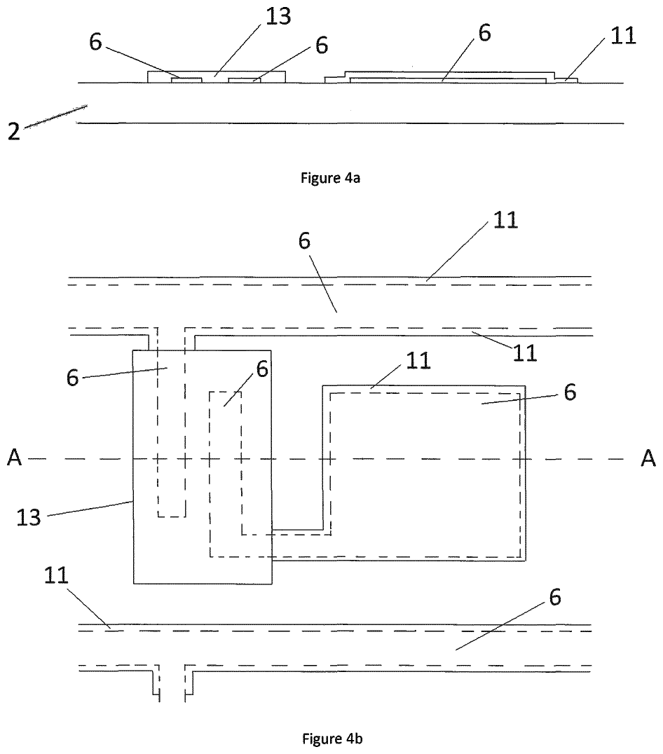

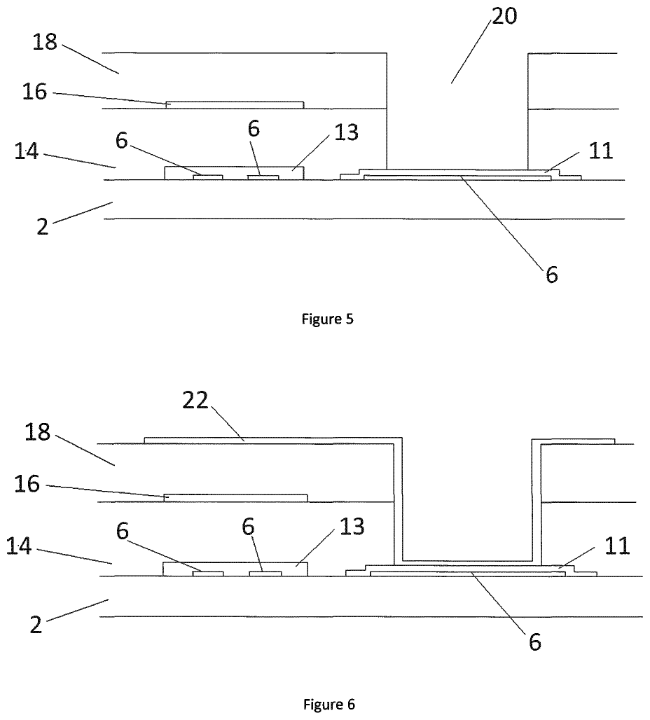

FIGS. 1 to 6 illustrate a process flow for a technique according to of an example embodiment of the present invention, in which FIGS. 1b, 2b, 3b and 4b are cross-sections along the dashed lines A-A in FIGS. 1a, 2a, 3a, and 4a, respectively.

For conciseness and clarity, the drawings focus on a single transistor region/single pixel in a thin film transistor (TFT)/multi-pixel array. The product device will typically contain a very large number of such transistor regions/pixels.

The embodiments described below are for the example of top-gate transistor arrays, but the techniques are also applicable to other types of transistor arrays.

For the purposes of this document, the term “source conductor” refers to a conductor in electrical series between a driver chip terminal and the semiconductor channel, and the term “drain conductor” refers to a conductor in electrical series with a driver chip terminal via the semiconductor channel.

The semiconductor channel material may comprise one or more organic semiconductor materials (such as e.g. organic polymer semiconductors), and/or one or more inorganic semiconductor materials.

The embodiments described below use a silver alloy for part of the source-drain conductor pattern. The relatively high work-function of the silver alloy is well-suited to the particular semiconductor channel material used in the research work carried out by the inventors, but other conductor materials (including also conductor materials with relatively low work functions) may be better suited to different semiconductor channel materials.

The embodiments described below use a conductive metal oxide (indium-tin-oxide (ITO)) for another part of the source-drain conductor pattern, which conductive metal oxide has a sufficiently low relative etch rate for the etchant used to pattern the layer of the particular semiconductor channel material used in the research work carried out by the inventors. Other conductor materials may be used, and other conductor materials may be more suitable for use in combination with other semiconductor channel materials.

A first step involves forming on the working surface of a substrate 2 a blanket layer of a silver alloy (e.g. silver alloy comprising 0.5% indium) by a vapour deposition process. In this example, the substrate 2 comprises an organic polymer support film (self-supporting plastic film, e.g. polyethylene naphthalate (PEN)), a patterned conductor layer providing light-shielding functionality in the product device, and an insulating, planarization layer at the surface. The substrate 2 is temporarily secured to a more rigid carrier (not shown), such as a glass plate, for processing the substrate 2 (including the processing steps described below), and is released from the carrier after completion of the processing.

The deposition of the silver alloy layer may be preceded by the deposition of one or more layers, such as one or more metal/alloy layers that function to improve the adhesion of the silver alloy to the workpiece, to create a stack of sub-layers which are then patterned together. Hereafter, the term “silver alloy layer” is used to mean a single layer or a stack of two or more layers having a silver alloy layer at the upper surface. The silver alloy layer is then patterned by photolithography and etching (using e.g. a mixture of phosphoric acid, acetic acid and nitric acid), to produce to a silver alloy subpattern 6.

Next, the working surface of the workpiece is coated with a blanket layer of a photoresist material, and the photoresist layer is exposed to an optical image of the pattern desired for the photoresist layer at a wavelength that effects a change in the solubility of the photoresist material. In this example, this is done using a photomask comprising a pattern of transmissive and non-transmissive regions that correspond to the pattern desired for the photoresist layer. After thus forming a latent solubility image in the photoresist layer, the solubility image is developed to form islands 9 of photoresist material in channel regions where the parts of the silver alloy subpattern 6 are in closest proximity.

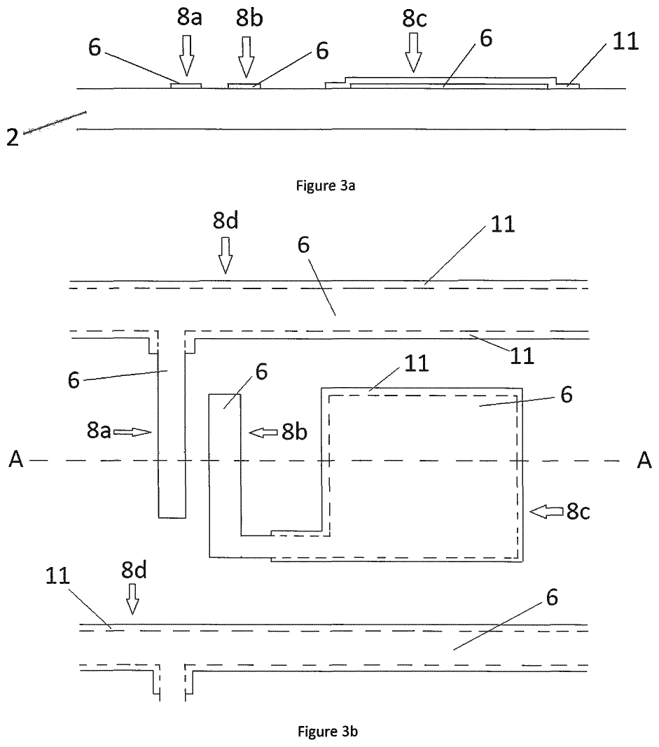

Next, a blanket layer of ITO is formed over the working surface of the workpiece (e.g. including over the photoresist islands 9) by a vapour deposition technique, and is patterned by photolithography and etching (using e.g. oxalic acid) to form an ITO subpattern 11. The ITO subpattern 11 comprises ITO in all regions where the silver alloy subpattern 6 comprises conductor material outside the photoresist islands 9. As shown in FIG. 3, the ITO subpattern 11 substantially matches the silver alloy subpattern 6 everywhere outside the photoresist islands 9, but each conductor element of the ITO subpattern 11 is slightly wider (has slightly larger dimensions in the plane of the workpiece) than the corresponding conductor element of the silver alloy pattern 6, in order to ensure that the silver alloy pattern 6 is completed covered by the ITO pattern 11 in all regions where the silver alloy subpattern 6 comprises conductor material outside the photoresist islands 9, even if there is some degree of error in alignment between the silver alloy subpattern 6 and the ITO subpattern 11.

After this ITO patterning, the photoresist islands 9 are removed (by e.g. exposing the workpiece to a photoresist stripper) to expose the silver alloy subpattern 6 therebelow.

The resulting source-drain conductor pattern defines at least (i) an array of source conductors, each source conductor associated with a respective column of transistors and extending beyond an edge of the array for connection to a respective terminal of a driver chip (not shown), and (ii) an array of drain conductors, each drain conductor associated with a respective transistor. Each source conductor includes an addressing line 8d that extends beyond an edge of the array for connection to a respective terminal (not shown) of a driver chip (not shown), and one or more source conductor fingers 8a for each transistor, which conductor fingers 8a branch off the addressing line 8d. The source conductor fingers 8a are the portions of the source conductor in closest proximity to the drain conductors. The drain conductor includes one or more drain conductor fingers 8b that extend substantially in parallel to the source conductor fingers 8a (e.g. interdigitated with the source conductor fingers 8a), which drain conductor fingers 8b are the parts of the drain conductor in closest proximity to the source conductor. Each drain conductor also defines a drain pad 8c connected to the drain conductor finger(s) 8b. The silver alloy sub-pattern 6 provides the upper surface of the source-drain conductor pattern in the channel regions where the source and drain conductors are in closest proximity, and the ITO sub-pattern 11 provides the upper surface of the source-drain conductor pattern in the regions of the addressing lines 8a and the drain pads 8c.

Good alignment of the ITO subpattern 11 with the silver alloy subpattern 6 is achieved by using the same alignment marks (not shown) for fixing the position of the photomasks used for patterning the photoresists in the processes of patterning the ITO and silver alloy layers. For example, the alignment marks may be defined by the above-mentioned light-shielding conductor layer forming part of the substrate 2.

A film of a solution of the semiconductor channel material (or a precursor thereto) is deposited (by e.g. spin coating) over the workpiece. This may be preceded by the formation on the exposed surfaces of the silver alloy subpattern 6 of one or more layers that improve charge transfer between the silver alloy subpattern 6 and the semiconductor channel material, such as e.g. a self-assembled monolayer of a suitable organic material.

After drying etc., the resulting layer of semiconductor channel material 10 is subjected to patterning to create an array of isolated islands 13 of semiconductor channel material, each island 13 providing the semiconductor channel for a respective transistor of the array. In this example, patterning the organic semiconductor channel material layer is performed using a plasma generated from a gas comprising oxygen (e.g. gas mixture of O₂ and SF₆), which involves chemical reaction of plasma species with exposed (unmasked) regions of the semiconductor channel material. However, the inventors for the present application have discovered that a plasma generated from a gas consisting essentially of one or more noble gases (e.g. argon) (and substantially excluding oxygen) may also be used to pattern an organic polymer semiconductor channel material.

The ITO sub-conductor pattern 11 serves to protect the silver alloy subpattern 6 during the process of patterning the semiconductor channel material layer by plasma etching.

In this example, the resulting pattern 13 of semiconductor channel material substantially matches the (now removed) masking pattern 9 of photoresist material used to mask parts of the silver alloy sub-pattern. This matching of patterns may be achieved by a process comprising: (i) coating the semiconductor channel material layer with a blanket layer of photoresist material, and projecting onto the photoresist layer the same image that was projected onto the photoresist layer used in the process of masking parts of the silver alloy subpattern 6 (this can be done by using the same photomask that was used for patterning the photoresist layer, and fixing the position of the photomask using the same alignment reference marks); (ii) developing the resulting latent solubility image in the photoresist layer; and (iii) using the resulting photoresist pattern as a mask for the plasma etching described above. One variation that allows larger process (processing tool) tolerances is to make the semiconductor channel material islands 13 slightly larger than the photoresist islands 9, so that even in the event of the maximum conceivable degree of alignment error, the semiconductor islands 13 nevertheless cover all of the regions in which the photoresist islands 9 were formed (and thereby cover all exposed parts of the silver alloy subpattern 6). This variation involves the use of a separate photomask for patterning the semiconductor channel material layer. The photomask for semiconductor patterning produces larger images of substantially the same island shape (as the photomask for producing the photoresist islands 9), in regions substantially centred on the regions in which the resist islands 9 are formed.

Further processing of the workpiece continues with the formation, in sequence, of: an (e.g. organic polymer) gate dielectric layer (or stack of gate dielectric layers) 14; a patterned conductor layer (or stack of conductor layers) 16 defining at least an array of gate conductors, each associated with a respective row of transistors and each extending beyond an edge of the TFT array for electrical connection to a respective terminal (not shown) of a driver chip (not shown); and an (e.g. organic polymer) insulator layer (or a stack of insulator layers) 18 over the patterned conductor layer. Each transistor is associated with a unique combination of gate and source conductors, whereby each pixel can be controlled independent of all other pixels.

A plasma generated from a gas comprising oxygen O₂ (e.g. a gas mixture of O₂ and sulphur hexafluoride SF₆) is used to create via holes 20 through the insulator layer(s) 18 and gate dielectric layer(s) 14 in regions where conductive interlayer connections are to be formed, including the regions where conductive interlayer connections are to be formed down to the drain pad 8c of each drain conductor. As mentioned above, the ITO subpattern 11 provides the upper surface of the source-drain conductor pattern in the regions where such interlayer connections are to be formed, whereby the via-holes 20 expose parts of the ITO subpattern 11 without exposing the silver alloy sub-pattern 6. The material of the first conductor sub-pattern exhibits a higher reduction in electrical conductivity than the material of the second conductor subpattern upon exposure to the conditions under which said patterning of said one or more layers is carried out; the second conductor subpattern exhibits substantially no reduction in electrical conductivity upon exposure to the conditions under which said patterning of said one or more layers is carried out.

A further conductor pattern is then formed over the workpiece, which further conductor pattern defines an array of pixel conductors 22 each connected to a respective drain conductor via a respective via-hole 20.

Without wishing to be bound by theory: (i) the ITO subpattern is considered to improve the performance of the product device by (a) preventing degradation of the electrical conductivity (breaks or oxidation) of the silver alloy subpattern 6 during the process of plasma etching the semiconductor channel material layer; and (b) better avoiding the formation of a non-conductor (metal oxide insulator) during the process of creating via holes 20 by plasma etching; and (ii) masking parts of the silver alloy subpattern before depositing the ITO material is considered to improve the performance of the product device by better avoiding degradation of the charge injection surface of the silver alloy subpattern 6 in the channel regions where the source and drain conductors are in closest proximity.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

1. A method of producing a device comprising a stack of layers defining an array of transistors and including one or more electrically conductive connections between levels, wherein the method comprises: forming a source-drain conductor pattern defining an array of source conductors each providing an addressing line for a respective set of transistors of the transistor array, and an array of drain conductors each associated with a respective transistor of the transistor array; wherein forming the source-drain conductor pattern comprises:
forming a first conductor subpattern which comprises conductor material at least in the regions of the addressing lines and provides the conductive surface of the source-drain conductor pattern at least in the regions where the source and drain conductors are in closest proximity;
masking the first conductor subpattern in regions where the source and drain conductors are in closest proximity;
thereafter forming a second conductor subpattern, which also comprises conductor material at least in the regions of the addressing lines and which provides the conductive surface of the source-drain conductor pattern in one or more interconnect regions where electrically conductive interlayer connections are to be formed to the source-drain conductor pattern;
thereafter de-masking the first conductor subpattern in the regions where the source and drain conductors are in closest proximity; and
patterning a layer of semiconductor channel material in situ over the source-drain conductor pattern.

2. The method according to claim 1, further comprising: forming one or more layers over the source-drain conductor pattern in the one or more interconnect regions, and patterning the one or more layers to expose the source-drain conductor pattern in the one or more interconnect regions; and wherein the material of the first conductor sub-pattern exhibits a higher reduction in electrical conductivity than the material of the second conductor subpattern upon exposure to the conditions under which the patterning of the one or more layers is carried out.

3. The method according to claim 2, wherein the material of the second conductor subpattern exhibits substantially no reduction in electrical conductivity upon exposure to the conditions under which the patterning of the one or more layers is carried out.

4. The method according to claim 2, wherein the conditions comprise a plasma generated from a gas comprising oxygen.

5. The method according to claim 1, wherein the second conductor subpattern comprises conductor material at least in all regions where the first conductor pattern comprises conductor material outside the regions where semiconductor channel material is retained.

6. The method according to claim 1, wherein: masking the first conductor subpattern comprises patterning a resist layer in situ on the first conductor subpattern to form an array of resist islands in an array of regions, and wherein patterning the layer of semiconductor channel material comprises forming an array of semiconductor channel materials, each semiconductor channel island substantially centred on a respective region of the array of regions, and comprising a magnified version of the shape of the respective resist island.

7. The method according to claim 1, wherein: masking the first conductor subpattern comprises patterning a resist layer in situ on the first conductor subpattern, and wherein the method further comprises using the same photomask for both patterning the resist layer and patterning the layer of semiconductor channel material.
